(19) United States
(12) Patent Application Publication
(10) Pub. No.: US 2020/0263050 A1
(43) Pub. Date: Aug. 20, 2020

(54) CONDUCTIVE INK COMPRISING DIACETYLENE DIOL MONOMER AND CONDUCTIVE POLYMER, AND METHOD FOR PRODUCING MICRO PATTERN USING THE SAME

(71) Applicant: INDUSTRY-UNIVERSITY COOPERATION FOUNDATION HANYANG UNIVERSITY, Seoul (KR)

(72) Inventors: Chan Woo LEE, Seoul (KR); Jong Man KIM, Seoul (KR); Su Min PARK, Daejeon (KR)

(73) Assignee: INDUSTRY-UNIVERSITY COOPERATION FOUNDATION HANYANG UNIVERSITY, Seoul (KR)

(21) Appl. No.: 16/650,210

(22) PCT Filed: Sep. 20, 2018
(86) PCT No.: PCT/KR2018/011115

§ 371 Date: Mar. 24, 2020

(30) Foreign Application Priority Data
Sep. 26, 2017 (KR) 10-2017-0124066

(51) Int. Cl. C09D 11/52; C08L 41/00; G03F 7/20; H01B 1/12; C08K 5/09; C08K 5/42; C08K 5/521

(52) U.S. Cl. CPC C09D 11/52; C08L 41/00; G03F 7/20; C08K 5/521; C08K 5/09; C08K 5/42; H01B 1/127

(57) ABSTRACT

A conductive ink containing a diacetylene diol monomer and a conductive polymer and a method for producing a fine pattern using the same are provided. The conductive ink comprises a conductive polymer and a diacetylene diol monomer represented by Chemical Formula 1 below: [Chemical Formula 1] HO—(R₁)ₙ—C≡C—C≡C—(R₂)ₘ—OH. In Chemical Formula 1, n and m are 1 to 10 irrespective of each other, R₁ and R₂, regardless of each other, are CRₐR_{b} or (CRₐR_{b})ₓO, Rₐ and R_{b} are each independently hydrogen or halogen, and x is an integer of 1 to 3. In Chemical Formula 1, R₁ and R₂ may be both CH₂, and n and m may be integers of 1 to 4 irrespective of each other.

### TECHNICAL FIELD

The present invention relates to a conductive ink and a method for producing a pattern using the same, and more particularly, to a conductive ink containing a conductive polymer and a method for producing a pattern using the same.

### BACKGROUND ART

In general, a pixel electrode applied to a display should be a transparent electrode, and should satisfy electrical and optical properties such as a sheet resistance of 10³ Ω/sq or less and a resistivity of 10⁻³ Ωcm or less as electrical properties, and a transmittance of 80% or more in the visible light region as a optical property.

Transparent electrodes are applied to various fields such as organic light emitting diodes (OLEDs), solar cells, touch screens, and keypads for mobile phones according to electrical conductivity. Researches to replace the ITO electrode, which is a conventional inorganic transparent electrode material, are being actively conducted, and new electrode materials using a metal thin film, an inorganic composite material including a conductive powder, or a conductive polymer as an organic material are being researched and developed.

There are two types of conductive polymers: a composite material made by incorporating conductive fillers such as metal and carbon into a general-purpose plastic matrix which is a non-conductor, and an intrinsically conductive polymer (ICP), in which the polymer matrix itself is inherently conductive.

Among them, as ICP, many different types of conductive polymers have been developed such as polyparaphenylene, polypyrrole, polythiophene, polyaniline, etc. However, conductive polymers such as polypyrrole and polyaniline have not yet exhibited suitable electrical conductivity for transparent electrode applications, and have poor workability due to insolubility in a general purpose solvent. In particular, in implementing a flexible display, which is considered as a next-generation display device, a conductive polymer patterning technology capable of realizing a micrometer wiring line width has been studied a lot academically and industrially to form a thin film transistor or wiring electrode inside the display device. The conductive polymer patterning technology is difficult to apply to the transparent electrode because the electrical conductivity is inevitably reduced as introducing a soluble functional group into the polymer to improve solubility thereof in the organic solvent.

PEDOT:PSS (poly (3,4-ethylenedioxythiophene):poly (styrenesulfonate)) is one of the most widely used conductive polymer materials because it has good transmittance in the visible region, it is dissolved in water so that it can be used for environmentally friendly solution process, and it is excellent in stability. However, it has very low electrical conductivity of 1 S/cm for use as a transparent electrode. Moreover, in order to increase the light transmittance, a thin film should be coated. In this case, the surface resistance is increased, which makes difficult to apply it as a transparent electrode.

### DISCLOSURE

### Technical Problem

Accordingly, an object of the present invention is to provide a conductive ink composition containing a conductive polymer, which can easily form a pattern using a photolithography process while greatly improving conductivity, and a method for forming conductive pattern using the same.

The objects of the present invention are not limited to the above-mentioned objects, and other objects not mentioned will be clearly understood by those skilled in the art from the following description.

### Technical Solution

One aspect of the present invention provides a conductive ink. The conductive ink comprises a conductive polymer and a diacetylene diol monomer represented by Chemical Formula 1 below.

HO—(R₁)ₙ—C≡C—C≡C—(R₂)ₘ—OH [Chemical Formula 1]

In Chemical Formula 1, n and m are 1 to 10 irrespective of each other. R₁ and R₂, regardless of each other, are CRₐR_{b} or (CRₐR_{b})ₓO. Rₐ and R_{b} are each independently hydrogen or halogen, and x is an integer of 1 to 3. In Chemical Formula 1, R₁ and R₂ may be both CH₂, and n and m may be integers of 1 to 4 irrespective of each other.

The conductive polymer may have a monomer represented by Chemical Formula 2 below.

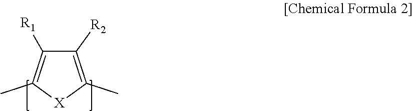

In Chemical Formula 2, X is S or Se, R₁ and R₂ are independently of each other hydrogen, halogen, hydroxy, alkyl of C1-C10, alkyloxy of C1-C10, or R₁ and R₂ join together to form a 3 to 5-membered alkylene, alkenylene, or alkylenedioxy group. The conductive polymer may be PEDOT (poly (3,4-ethylenedioxythiophene)).

The conductive ink may further include a polymer anion which is a polymerized carboxylic acid or polymerized sulfonic acid. The conductive ink may further contain water, alcohols, or mixtures thereof as a solvent.

The diacetylene diol monomer may be contained in an amount of 1 to 600 parts by weight, for example 100 to 400 parts by weight, specifically 100 to 250 parts by weight based on 100 parts by weight of the conductive polymer.

Another aspect of the present invention provides a preparation method for a fine pattern. The method comprises forming a conductive film by coating a conductive ink including a conductive polymer and a diacetylene diol monomer represented by the Chemical Formula 1 on a substrate. A photomask is disposed on the conductive film and ultraviolet rays are irradiated on the photomask to provide a first region having the conductive polymer and a polydiacetylene formed by crosslinking the diacetylene diol monomer and a second region in which the diacetylene diol monomer remains in the conductive film. The second region is selectively removed to form a conductive polymer fine pattern.

The substrate may be a silicon wafer, glass substrate, plastic substrate, paper or metal substrate. The conductive ink may contain 0.1 to 300 parts by weight of the diacetylene diol based on 100 parts by weight of the conductive polymer. The selectively removing of the second region may be performed using water, alcohol, or a mixture thereof.

The conductive polymer fine pattern may be doped with one or more dopants selected from the group consisting of perfluorinated acid, sulfuric acid, sulfonic acid, formic acid, hydrochloric acid, perchloric acid, nitric acid, acetic acid, DMF (dimethylformamide), DMSO (dimethyl sulfoxide), hydroquinone, catechol, and ethylene glycol. The dopant may be perfluorinated acid represented by the Chemical Formula 3 below.

CF₃—(CF₂)ₙ-A [Chemical Formula 3]

In Chemical Formula 3, n is an integer from 3 to 20, and A is SO₃H, OPO₃H or CO₂H. n in Chemical Formula 3 may be an integer from 6 to 8, and A is SO₃H.

The conductive polymer fine pattern may be an electrode of an organic electronic device.

### Advantageous Effects

According to the present invention as described above, a conductive ink composition containing a conductive polymer, which may easily form a pattern using a photolithography process while greatly improving conductivity, and a method of forming a conductive pattern using the same may be provided.

However, the effects of the present invention are not limited to the above-mentioned effects, and other effects not mentioned will be clearly understood by those skilled in the art from the following description.

### DESCRIPTION OF DRAWINGS

FIGS. 1A to 1C are schematic views illustrating a method of producing a fine pattern according to an embodiment of the present invention.

FIG. 2 is a graph showing the conductivity of the conductive film according to the weight percentage of diacetylene diol.

FIGS. 3A, 3B, 3C, and 3D are optical photographs of fine patterns manufactured by using the conductive ink compositions according to Conductive Ink Preparation Examples 6 and 10 to 12.

FIGS. 4A, 4B, 4C, and 4D are photographs taken during the process of performing the Fine Pattern Preparation Example 1 and the Fine Pattern Doping Example 1 using the conductive ink composition according to Conductive Ink Preparation Example 6.

FIGS. 5A and 5B show the thickness difference before and after development and the thickness and width of the formed pattern during perfoming the Fine Pattern Preparation Example 1, respectively.

FIGS. 6A, 6B, 6C, and 6D are photographs of the fine patterns obtained through the Fine Pattern Preparation Examples 1 to 3 using the conductive ink composition according to Conductive Ink Preparation Example 6.

FIG. 7A is an ultraviolet-visible spectrum, FIG. 7B is an FT-IR spectrum, FIGS. 7C and 7D are Raman spectrums, FIG. 7E is an XRD (X-ray diffraction) graph, and FIG. 7F is a graph showing conductivity change of the resultants obtained in the course of performing the Fine Pattern Preparation Example 1 using the conductive ink composition according to Conductive Ink Preparation Example 6.

FIGS. 8A and 8B are, respectively, graphs showing UV-vis absorption spectra and transmission spectra of the conductive pattern obtained by performing Fine Pattern Preparation Example 1 using the conductive ink composition according to Conductive Ink Preparation Example 6 and the doped conductive pattern obtained by performing Fine Pattern Doping Example 1 using the conductive pattern.

FIG. 9 shows infrared spectra of the conductive film obtained during performing Fine Pattern Preparation Example 1 using the conductive ink composition according to Conductive Ink Preparation Example 6 and the doped conductive film obtained by performing Fine Pattern Doping Example 1 on the conductive film.

FIG. 10 is a graph showing the conductivity of PEDOT:PSS film, the fine pattern obtained according to the Fine Pattern Preparation Example 1 using the conductive ink composition of the Conductive Ink Preparation Example 1, the fine pattern doped with sulfuric acid, and the fine pattern doped with PFOSA.

FIG. 11 is a graph showing the relative change in conductivity over time after doping fine pattern with sulfuric acid or PFOSA.

### MODES OF THE INVENTION

Hereinafter, exemplary embodiments of the present invention will be described in detail with reference to the accompanying drawings in order to describe the present invention in more detail. However, the invention is not limited to the embodiments described herein but may be embodied in other forms. In the drawings, where a layer is said to be “on” another layer or substrate, it may be formed directly on the other layer or substrate, or a third layer may be interposed therebetween. In the present embodiments, “first”, “second”, or “third” is not intended to impose any limitation on the components, but should be understood as a term for distinguishing the components.

As used herein, unless otherwise defined, “alkyl” refers to an aliphatic hydrocarbon group and may be “saturated alkyl” that does not include a double bond or a triple bond. The saturated alkyl group can be linear.

As used herein, unless otherwise defined, “alkylene” refers to a divalent group which is a radical of an alkane which is a saturated hydrocarbon, and may be linear alkylene.

In the present specification, when it is described as “carbon number X to carbon number Y”, it should be construed that the case having the number of carbon atoms corresponding to all integers between carbon number X and carbon number Y also described.

As used herein, “halogen” or “halo” is an element belonging to Group 17, specifically, it may be a fluorine, chlorine, bromine, or iodine group.

In the present specification, when “X to Y” is described, the number corresponding to all integers between X and Y should be interpreted as being described together.

Conductive Ink with Diacetylene Diol

A conductive ink according to an embodiment of the present invention may contain 100 parts by weight of a conductive polymer, 1 to 600 parts by weight of a diacetylene diol monomer, and a remainder of a solvent. The solvent may be a polar protic solvent, for example, an alcohol, water or a mixture thereof. For example, the solvent may be water. The alcohol may be methanol, ethanol, propanol, or a mixture thereof, but specifically ethanol.

The diacetylene diol monomer may be a substance having diacetylene and a diol in a molecule, for example, may be represented by the following Chemical Formula 1. The diacetylene diol monomer may exhibit water solubility. In addition, as an example, the diacetylene diol monomer may be contained in the conductive ink at 1 to 600 parts by weight. The weight ratio of the diacetylene diol monomer may be selected in consideration of the viscosity of the conductive ink and the conductivity of the film using the conductive ink.

HO—(R₁)ₙ—C≡C—C≡C—(R₂)ₘ—OH [Chemical Formula 1]

In Chemical Formula 1, n and m may be integers of 1 to 10, specifically 1 to 4 irrespective of each other, R₁ and R₂ may be CRₐR_{b} or (CRₐR_{b})ₓO irrespective of each other, Rₐ and R_{b} may be, regardless of each other, hydrogen or a halogen group, and x may be an integer of 1 to 3. The halogen group may be F, Cl, Br, or I, but may be F as an example.

In one example, both R₁ and R₂ may be CH₂, where n and m may be integers of 1 to 4, regardless of each other. In this case, the diacetylene diol monomer may be well dissolved in water.

The conductive polymer may have a monomer represented by Chemical Formula 2 below.

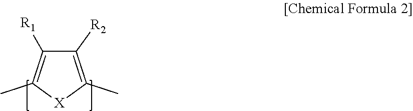

In Chemical Formula 2,

X may be S or Se,

R₁ and R₂ may be, independently of each other, hydrogen, halogen, hydroxy, C1-C10 alkyl, C1-C10 alkyloxy, or R₁ and R₂ may join together to form a 3 to 5 membered alkylene group, alkenylene group, alkylenedioxy group. The alkylenedioxy group may be a methylenedioxy group, an ethylenedioxy group, or a propylenedioxy group. Specifically, the conductive polymer may be PEDOT (poly (3,4-ethylenedioxythiophene)).

The conductive polymer may be a water-soluble polymer. For example, some of the aromatic rings forming the main chain of the conductive polymer, i.e., thiophenes or selenophenes, may exhibit positive charges. The conductive ink may further include a polymer anion for stabilizing the conductive polymer having the positive charge on the main chain. The polymer anion may be a polymerized carboxylic acid or a polymerized sulfonic acid. The polymerized carboxylic acid may be polyacrylic acid, polymethacrylic acid, or polymaleic acid, and the polymerized sulfonic acid may be polystyrene sulfonic acid or polyvinyl sulfonic acid. The polymer anion may be contained in the conductive ink in an amount of 10 to 200 parts by weight, for example, 100 to 150 parts by weight.

The conductive ink may be obtained by dissolving the diacetylene diol monomer in a conductive polymer aqueous solution in which the conductive polymer and the polymer anion are dissolved. The conductive ink may show a solution state without aggregation. To this end, a homogeneous solution can be obtained by further ultrasonication after mixing the conductive polymer aqueous solution and the diacetylene diol monomer.

Fine Pattern Manufacturing Method Using Conductive Ink

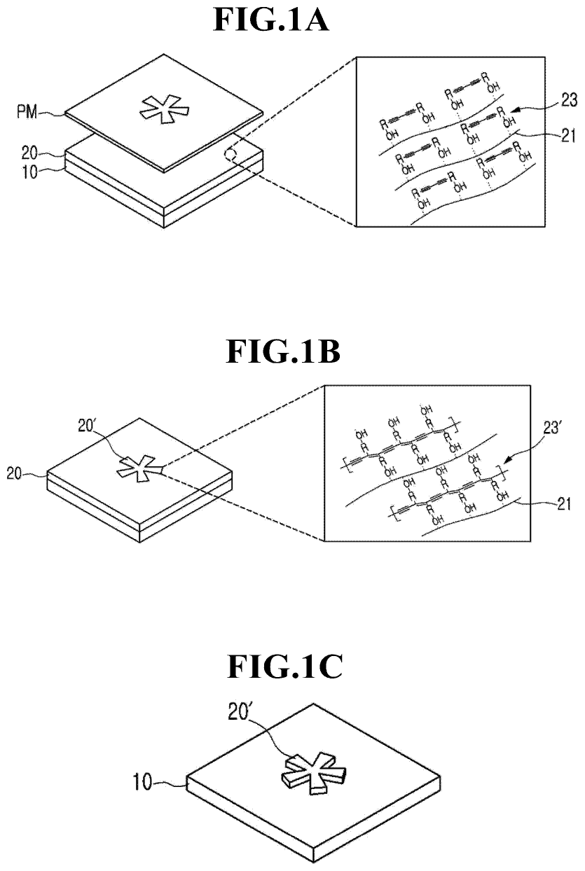

FIGS. 1A to 1C are schematic views illustrating a method of producing a fine pattern according to an embodiment of the present invention.

Referring to FIG. 1A, the conductive ink described above may be coated on a substrate 10 to form a conductive film 20. The substrate may be referred to as a base material or a support, and may be a silicon wafer, a glass substrate, a polymer substrate, a paper substrate, or a metal substrate. In one example, another thin film may already be formed on the substrate.

The coating may be a wet coating, for example, spin coating or doctor blade, but is not limited thereto. For example, the coating may be spin coating, and the conductive film having an appropriate thickness may be obtained with a minimum number of coatings.

The conductive film 20 may contain a conductive polymer 21, a diacetylene diol monomer 23, and a solvent, and may further contain a polymer anion for stabilizing the conductive polymer. The formed conductive film 20 may be dried, in this case at least some or almost all of the solvent may be removed.

The diacetylene diol monomer 23 is an amphiphilic substance having both a hydrophilic functional group and a hydrophobic functional group in the molecule. Therefore, in the conductive film 20, the diacetylene diol monomer 23 may be self-assembled onto the conductive polymer 21 by interaction such as hydrogen bonding. In this case, the conductive polymer 21 may be deformed from the benzoid structure to the quinoid structure, the conductive polymer 21 may be changed into a linear or extended coil form, and its conjugate length may be increased to improve conductivity. In addition, as the diacetylene diol monomer 23 includes two alcohol groups in the molecule, the dielectric constant thereof may be relatively large, and thus the conductivity of the conductive film 20 may be further improved. As the diacetylene diol monomer 23 exhibits this action, it may be said to play a role of a dopant in addition to the role of the crosslinking agent cross-linked by ultraviolet rays, as described later.

A photomask PM having a light transmissive region may be disposed on the conductive film 20, and ultraviolet rays may be irradiated onto the photomask. Ultraviolet ray exposure may be performed by irradiating ultraviolet rays of 220 to 330 nm for 10 seconds to 5 minutes.

Referring to FIG. 1B, the diacetylene diol may be cross-linked in the region 20′ in which the ultraviolet rays are irradiated in the conductive film 20 to form a polydiacetylene 23′ of following Chemical Formula 1A. Meanwhile, the diacetylene diol may remain in the region where ultraviolet rays are blocked by the photomask PM.

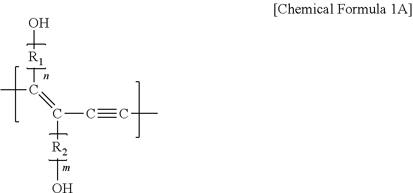

In Chemical Formula 1A, R₁ and R₂ may be CRₐR_{b} or (CRₐR_{b})ₓO irrespective of each other, Rₐ and R_{b} may be hydrogen or a halogen group regardless of each other, and x may be an integer of 1 to 3. In addition, each of n and m may be an integer of 1 to 10, specifically 1 to 4 irrespective of each other. The halogen group may be F, Cl, Br, or I, but may be F as an example. In one example, both R₁ and R₂ may be CH₂, where n and m may be integers of 1 to 4, regardless of each other.

The ultraviolet irradiation region 20′ may have yellow color as the polydiacetylene formed by crosslinking the diacetylene diol monomer has a π-conjugated main chain due to the superposition of t-orbitals.

Referring to FIG. 1C, the radiation-exposed conductive film 20 may be developed. Specifically, the substrate having the radiation-exposed conductive film 20 may be dipped in a developing solution and reacted for a predetermined time. The developer may be water, alcohol or a mixture thereof. In one example, it can be developed using water and then washed with alcohol, in particular ethanol.

In the developing process, the region not irradiated with ultraviolet rays may be selectively washed out by the developer as the water-soluble diacetylene diol monomer remains, and the ultraviolet irradiated region 20′ may remain as a fine pattern 20′ containing the polydiacetylene and the conductive polymer due to polydiacetylene having insolubility in water. Since the fine pattern is formed to correspond to the light transmitting area of the photomask, it may be called a negative pattern. In addition, the fine pattern may have a line width of nano size or micro size.

In order to form such a fine pattern with high resolution, the content of diacetylene diol in the conductive ink may be controlled. As an example, the content of the diacetylene diol may be 0.1 to 300 parts by weight, specifically 10 to 300 parts by weight, and more specifically 10 to 250 parts by weight based on 100 parts by weight of the conductive polymer. In addition, considering the conductivity of the fine pattern, the content of the diacetylene diol may be 100 to 250 parts by weight, about 110 to 250, or about 130 to 250 parts by weight. However, even when the content of the diacetylene diol is low and thus the conductivity of the fine pattern is low, the conductivity of the fine pattern may be further improved through the doping process described later.

Conductivity may be improved by further doping the conductive polymer in the fine pattern by adding a dopant on the fine pattern 20′. The dopant may be at least one selected from the group consisting of perfluorinated acid, sulfuric acid, sulfonic acid, formic acid, hydrochloric acid, perchloric acid, nitric acid, acetic acid, DMF (dimethylformamide), DMSO (dimethyl sulfoxide), hydroquinone, catechol, and ethylene glycol. The sulfonic acid may be selected from the group consisting of methanesulfonic acid, trifluoromethanesulfonic acid, perchloric acid, benzenesulfonic acid, and paratoluenesulfonic acid, but is not limited thereto.

The perfluorinated acid may be represented by the following Chemical Formula 3.

CF₃—(CF₂)ₙ-A [Chemical Formula 3]

In the above formula,

n may be 3 to 20, and A may be SO₃H, OPO₃H or CO₂H.

As an example, n in Chemical Formula 3 may range from 4 to 9, specifically, 6 to 8, and A may be SO₃H.

The perfluorinated acid represented by Chemical Formula 3 may have superhydrophobic and chemical resistant properties due to fluorine atoms being substituted for hydrogens in a carbon main chain, and also may have a high hydrophilicity due to a sulfonic acid group, a phosphoric acid group, or a carboxylic acid group at the end of the carbon main chain. Therefore, it has an amphiphilic molecular structure that has both hydrophilicity and hydrophobicity in the molecule. In general, an amphiphilic material exhibits a layered structure in which molecules are spontaneously oriented as in cell membranes. The perfluorinated acid exhibits amphiphilic properties as it has a superhydrophobic alkyl chain and a hydrophilic functional group (sulfonic acid, etc.), and may have a layered structure spontaneously oriented on the conductive polymer, leading to the extended structure of the conductive polymer. In addition, the hydrophilic functional group (sulfonic acid, etc.) may improve the electrical conductivity of the conductive polymer by cation doping the conductive polymer. Accordingly, the perfluorinated acid may help electrons flow more easily in the main chain of the conductive polymer, that is, the conjugated polymer.

In general, conductive polymers are oxidized by moisture and various contaminants in the air, and thus have vary poor long term stability in terms of electrical conductivity. Perfluorinated alkyl chains not only induce spontaneous oriented layer structure but also induce superhydrophobic properties, and can effectively serve to block water or air pollutants in the air. As a result, the perfluorinated acid may serve to straighten the conductive polymer chain to have a molecular structure through which electric charges can flow well, and at the same time, may serve to improve long-term stability of electrical conductivity of the fine pattern.

In Formula 3, n may be 3 to 20, and most preferably n may be 4 to 9. If the value of n is less than 3, it is difficult to maintain the electrical conductivity of the conductive polymer in the long term. If the value of n is more than 20, the size of the molecule is large, so that it is difficult to penetrate between the polymer chains and thus it is difficult to dope the polymer, thereby lowering the electrical conductivity.

In the doping step, the fine pattern may be treated with a solution containing the dopant, specifically, an aqueous solution containing the dopant. The dopant aqueous solution may contain about 10 to 60 wt %, specifically about 30 to 50 wt %, more specifically 35 to 45 wt % of the dopant. Thereafter, washing the dopant not penetrated into the fine pattern with a solvent such as ethanol, and drying the washed pattern. At this time, the drying may be carried out at 60 to 160° C. Treatment of the fine pattern with a solution containing the dopant may include spraying, coating, or adding a solution containing the dopant on the fine pattern, or dipping the substrate on which the fine pattern is formed in the solution containing the dopant. As an example, a method of dipping may be used.

The prepared fine pattern 20′ may include the conductive polymer and polydiacetylene represented by Chemical Formula 1A. The polydiacetylene may be self-assembled by an interaction such as hydrogen bonding to the conductive polymer; thus the conductive polymer may be transformed from a benzoid structure to a quinoid structure to have linear or extended-coil form. Therefore, the conjugation length of the conductive polymer can be increased and the conductivity can be improved. In addition, the fine pattern 20′ may further include a perfluorinated acid represented by Chemical Formula 3 as an example of a dopant. Furthermore, the fine pattern 20′ may further include a polymer anion which is a polymerized carboxylic acid or a polymerized sulfonic acid.

Meanwhile, the fine pattern may be used as an electrode in a display device or an electrochemical device, specifically in an organic electronic device. The display device may be an organic light emitting diode, and the electrochemical device may be an organic solar cell or a dye-sensitized solar cell. The organic electronic device may be an organic thin film transistor. Other electrochemical devices can be capacitors.

Method for Manufacturing Conductive Film Using Conductive Ink

A conductive film using the conductive ink according to the present embodiment may be manufactured with omitting the patterning step including the exposure and development steps of the above-described fine pattern manufacturing method. Specifically, after the conductive ink is coated on a substrate and dried to form the conductive film, the above-described dopant may be applied onto the conductive film. In this case, the diacetylene diol in the conductive ink may be contained in an amount of about 100 to 400 parts by weight, about 110 to 350 parts by weight, or about 130 to 260 parts by weight based on 100 parts by weight of the conductive polymer.

As such, while the patterning is omitted, the doping step may be performed. Alternatively, the conductive film may be patterned using another photoresist after forming the conductive film, or the conductive film may be patterned using another patterning method such as an imprint method, and then the doping step may be performed.

The prepared conductive film may also include the conductive polymer and polydiacetylene represented by Chemical Formula 1A. The polydiacetylene may be self-assembled by an interaction such as hydrogen bonding to the conductive polymer, and thus the conductive polymer may be transformed from a benzoid structure to a quinoid structure to form linear or extended-coil form; therefore, the conjugation length can be increased and the conductivity can be improved. In addition, the conductive film may further include a perfluorinated acid represented by Chemical Formula 3 as an example of the dopant. Furthermore, the conductive film may further include a polymer anion which is a polymerized carboxylic acid or a polymerized sulfonic acid.

Hereinafter, preferred examples are provided to aid the understanding of the present invention. However, the following experimental example is only for helping understanding of the present invention, and the present invention is not limited by the following experimental example.

Examples of Preparing Conductive Ink Compositions for Optical Micro-Processing

### Conductive Ink Composition Preparation Examples 1-9

2,4-hexadiyne-1,6-diol (HDO) was added to Ig of PEDOT:PSS aqueous solution (sigma-aldrich) including 0.5 wt % of PEDOT and 0.8 wt % of PSS by weight as shown in Table 1, and sufficiently dissolved by sonication for 10 minutes to obtain a mixed solution. The mixed solution was filtered using a 0.45 mm filter to remove impurities to obtain conductive ink compositions for optical microprocessing according to Preparation Examples 1-9.

TABLE 1

| | | | | | Parts by weight of | | | |
|---|---|---|---|---|---|---|---|---|
| | | | | | HDO | | Parts by weight of | |
| | | | | | for 100 parts by | | HDO | |
| | | | | | weight of | | for 100 parts by | |
| | HDO | | PEDOT:PSS | PEDOT | PEDOT:PSS | | weight of PEDOT | |
| Preparation | 0.65 | mg | | | 5 | parts by weight | 13 | parts by weight |
| Example 1 | | | | | | | | |
| Preparation | 1.3 | mg | | | 10 | parts by weight | 26 | parts by weight |
| Example 2 | | | | | | | | |
| Preparation | 3.25 | mg | | | 25 | parts by weight | 65 | parts by weight |
| Example 3 | | | | | | | | |
| Preparation | 5.2 | mg | | | 40 | parts by weight | 104 | parts by weight |
| Example 4 | | | | | | | | |
| Preparation | 5.85 | mg | 13 mg | 5 mg | 45 | parts by weight | 117 | parts by weight |
| Example 5 | | | | | | | | |
| Preparation | 6.5 | mg | | | 50 | parts by weight | 130 | parts by weight |
| Example 6 | | | | | | | | |
| Preparation | 13 | mg | | | 100 | parts by weight | 260 | parts by weight |
| Example 7 | | | | | | | | |
| Preparation | 16.25 | mg | | | 125 | parts by weight | 325 | parts by weight |
| Example 8 | | | | | | | | |
| Preparation | 26 | mg | | | 200 | parts by weight | 520 | parts by weight |
| Example 9 | | | | | | | | |

### Conductive Ink Composition Preparation Examples 10-12

Compositions were prepared in the same manner as in Preparation Example 6, except that 6.5 mg of 3,5-octadiyne-1,8-diol (Composition Preparation Example 10), 6.5 mg of 4,6-decadiin-1,10-diol (Composition Preparation Example 11), or 6.5 mg of 5,7-dodecadiyn-1,12-diol (Composition Preparation Example 12) was used instead of 6.5 mg of 2,4-hexadiyne-1,6-diol (HDO).

### FINE PATTERN PREPARATION EXAMPLES

### Fine Pattern Preparation Example 1

One of the prepared Conductive Ink Compositions was spin-coated on a glass substrate to obtain a uniform conductive film and then dried to measure the conductivity of the conductive film. A photomask having a light transmission pattern was disposed on the conductive film, and ultraviolet rays having a wavelength of 254 nm (12.5 mWcm⁻²) were irradiated for 10 seconds using the photomask as a mask. After ultraviolet exposure, the substrate having the conductive film was immersed in water to remove the non-UV irradiated portion, and then washed with ethanol to form a conductive pattern. Thereafter, the conductive pattern was dried, and the electrical conductivity of the dried conductive pattern was measured.

### Fine Pattern Preparation Examples 2 and 3

Fine pattern was prepared in the same manner as in Fine Pattern Preparation Example 1, except that a silicon wafer (Fine Pattern Preparation Example 2) or a PET substrate (Fine Pattern Preparation Example 3) was used instead of the glass substrate.

### FINE PATTERN DOPING EXAMPLES

### Fine Pattern Doping Example 1

The substrate on which the fine pattern was prepared was immersed for 10 minutes in a 40 wt % aqueous solution of perfluorooctanesulfonic acid (PFOSA), and then taken out and sequentially washed with water and ethanol, thereby doping the fine pattern.

### Fine Pattern Doping Example 2

The fine pattern was doped using the same method as the Fine Pattern Doping Example 1 except that 18 M sulfuric acid solution was used instead of the PFOSA solution.

Table 2 summarizes the conductivity of the conductive film obtained in the Fine Pattern Preparation Examples and the state of the formed conductive pattern.

TABLE 2

| | Parts by weight of HDO | | Conductivity of the | |
|---|---|---|---|---|
| Ink | for 100 parts by weight | | conductive film | Pattern |
| Composition | of PEDOT | | (S/cm) | Quality |
| Preparation | 13 | parts by weight | 3 | Good |
| Example 1 | | | | |
| Preparation | 26 | parts by weight | 4 | Good |
| Example 2 | | | | |
| Preparation | 65 | parts by weight | 47 | Good |
| Example 3 | | | | |
| Preparation | 104 | parts by weight | 1157 | Good |
| Example 4 | | | | |
| Preparation | 117 | parts by weight | 2325 | Good |
| Example 5 | | | | |
| Preparation | 130 | parts by weight | 3040 | Good |
| Example 6 | | | | |
| Preparation | 260 | parts by weight | 4014 | Slightly |
| Example 7 | | | | Bad |
| Preparation | 325 | parts by weight | 1353 | Not |
| Example 8 | | | | developed |
| Preparation | 520 | parts by weight | 705 | Not |
| Example 9 | | | | developed |

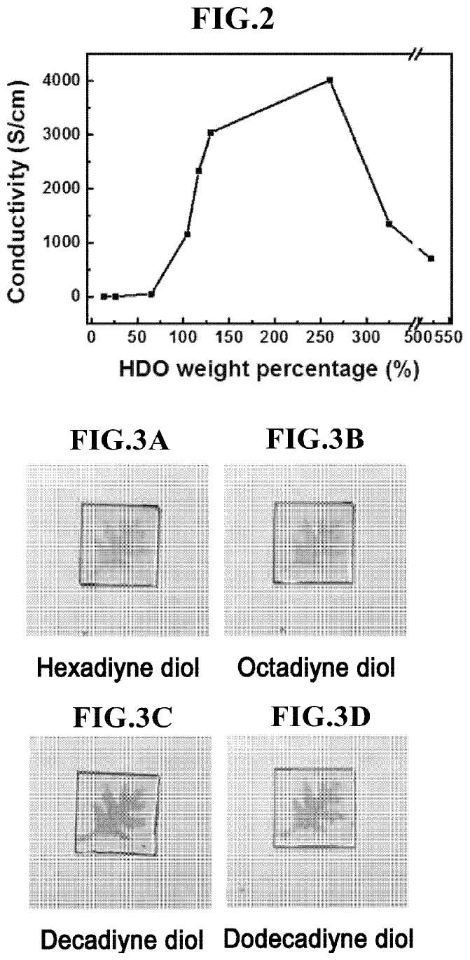

FIG. 2 is a graph showing the conductivity of the conductive film according to the weight percentage of the diacetylene diol.

Referring to FIG. 2 and Table 2, the conductivity of the PEDOT:PSS conductive film was hardly increased (47 S/cm) until the parts by weight of HDO, which is a diacetylene diol, was about 65 parts by weight based on 100 parts by weight of PEDOT. From 100 parts by weight (Preparation Example 4) showed a large increase, such as the conductivity exceeds 1000 S/cm. After that, when about 260 parts by weight was added, the conductivity exceeded 4000 S/cm, and when added more, the conductivity was decreased again. From these results, it can be seen that the diacetylene diol may be added about 100 to 400 parts by weight based on 100 parts by weight of PEDOT to obtain the conductivity of the conductive film of more than 1000 S/cm. Furthermore, it can be seen that the diacetylene diol may be added about 110 to 350 parts by weight based on 100 parts by weight of PEDOT to obtain the conductivity of the conductive film of more than 2000 S/cm. Furthermore, it can be seen that the diacetylene diol may be added about 130 to 260 parts by weight based on 100 parts by weight of PEDOT to obtain the conductivity of the conductive film of more than 3000 S/cm.

Meanwhile, in the case of producing a pattern by ultraviolet exposure and development of the conductive film, it can be seen that the pattern is not formed when the content of the diacetylene diol exceeds 300 parts by weight (Ink Composition Preparation Example 8). In addition, it can be seen that the content of the diacetylene diol may be 250 parts by weight or less (Ink Composition Preparation Examples 1 to 6) in order to obtain a good pattern.

Therefore, when the conductive film is used without patterning the conductive film according to the embodiment of the present invention, or when patterning is performed by using another photoresist layer other than the method of radiation exposing and developing the conductive film, or when other patterning such as an imprint method is performed, in terms of the conductivity of the conductive film, the diacetylene diol in the conductive ink may be contained as about 100 to 400 parts by weight, about 110 to 350 parts by weight, or about 130 to 260 parts by weight based on 100 parts by weight of the conductive polymer.

However, when the conductive film is to be radiation exposed and developed to form a conductive pattern, a good pattern should be considered first, so that the diacetylene diol in the conductive ink is about 10 to 300 parts by weight, about 10 to 250 parts by weight, and further in consideration of the conductivity of the pattern, about 100 to 250 parts by weight, about 110 to 250, or about 130 to 250 parts by weight based on 100 parts by weight of the conductive polymer. Meanwhile, when the conductivity of the pattern is not satisfactory, the pattern may be additionally doped.

FIGS. 3A, 3B, 3C, and 3D are optical photographs of fine patterns manufactured by using the conductive ink compositions according to Conductive Ink Preparation Examples 6 and 10 to 12.

Referring to FIGS. 3A, 3B, 3C, and 3D, in the case of hexadiyne diol and octadiyne diol, a high resolution pattern is obtained, but in the case of decadiyne diol and dodecadiyne diol, a slightly lower resolution pattern is obtained. This means that the shorter the hydrocarbon chain length of the diacetylene diol compound is, the larger the hydrophilicity, the greater the solubility in water, so that a homogeneous composition can be obtained during ink composition preparation, and also it can be washed clean during development.

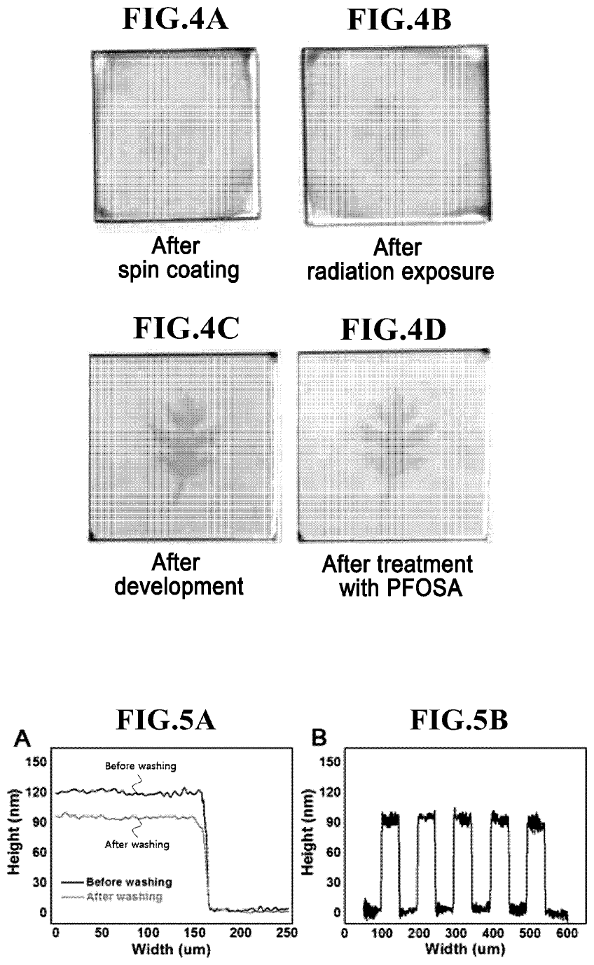

FIGS. 4A, 4B, 4C, and 4D are photographs taken during the process of performing the Fine Pattern Preparation Example 1 and the Fine Pattern Doping Example 1 using the conductive ink composition according to Conductive Ink Preparation Example 6.

Referring to FIGS. 4A, 4B, 4C, and 4D, after spin coating of the conductive ink composition on the glass substrate and after the radiation exposure, the pattern is not confirmed, but after the development, the pattern is confirmed, and the pattern is maintained even after doping with PFOSA.

FIGS. 5A and 5B show the thickness difference before and after development and the thickness and width of the formed pattern during perfoming the Fine Pattern Preparation Example 1, respectively.

Referring to FIG. 5A, it can be seen that the thickness of the film before development after spin coating was about 120 nm and the thickness of the film developed with DI water was reduced to 95 nm. This reduction in thickness was presumably due to the washing away of the unpolymerized HDO monomer and the non-conductive PSS.

Referring to FIG. 5B, it can be seen that the pattern obtained after development is a clear pattern having subpatterns each having a width of about 70 μm and a thickness of 95 nm.

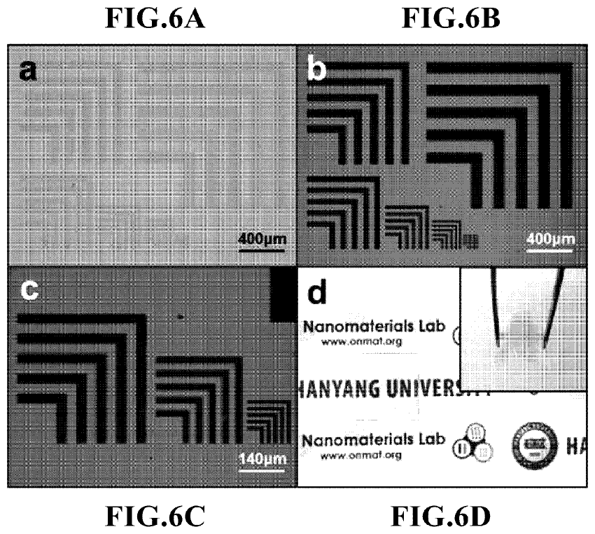

FIGS. 6A, 6B, 6C, and 6D are photographs of the fine patterns obtained through the Fine Pattern Preparation Examples 1 to 3 using the conductive ink composition according to Conductive Ink Preparation Example 6.

Referring to FIGS. 6A, 6B, 6C, and 6D, fine patterns in micrometer sizes, specifically, having a line width of about 10 to 200 jam, are formed clearly such that the end of the pattern has a clear shape not only on glass substrate (FIG. 6A) but also on silicon wafer substrates (FIGS. 6B and 6C) and on flexible and transparent PET substrate (FIG. 6D).

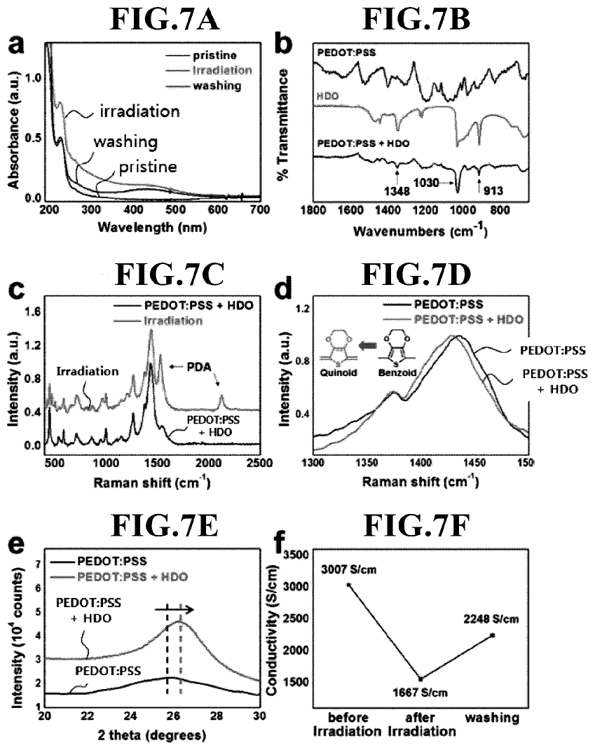

FIG. 7A is an ultraviolet-visible spectrum, FIG. 7B is an FT-IR spectrum, FIGS. 7C and 7D are Raman spectrums, FIG. 7E is an XRD (X-ray diffraction) graph, and FIG. 7F is a graph showing conductivity change of the resultants obtained in the course of performing the Fine Pattern Preparation Example 1 using the conductive ink composition according to Conductive Ink Preparation Example 6.

Referring to FIG. 7A, the film formed by spin coating the conductive ink composition containing HDO and PEDOT:PSS is referred to as “pristine”. After irradiating ultraviolet rays on the formed film, the irradiated film (referred to as “irradiation”) was developed and washed. The washed film is referred to as “washing”. The pristine film (pristine), the irradiated film (irradiation), and the washed film (washing) exhibit absorption peaks at about 225 nm in the ultraviolet-visible spectrum, which is a peak due to PSS. However, this PSS peak at 225 nm was reduced by water washing in the development process. From this, it can be estimated that the HDO monomers which have not been polymerized and the excessively added PSS are removed in the developing step. Meanwhile, after irradiating the film with ultraviolet radiation of 254 nm, a new peak appeared around 450 nm, which is due to the color change due to the polymerization of HDO (red line).

Referring to FIG. 7B, the FT-IR spectrum of the conductive ink composition containing HDO and PEDOT:PSS (black line), the FT-IR spectrum of HDO (red line), and the FT-IR spectrum of PEDOT:PSS (blue line) are shown. The FT-IR spectrum of the conductive ink composition containing HDO and PEDOT: PSS shows all the characteristic peaks of HDO at 1348 cm⁻¹, 1030 cm⁻¹, and 913 cm⁻¹, together with the broad PEDOT:PSS peaks; therefore, it can be seen that HDO and PEDOT: PSS were well mixed in the conductive ink composition containing HDO and PEDOT: PSS.

Referring to FIG. 7C, from the Raman spectrum of the conductive ink composition containing HDO and PEDOT:PSS (black line) and the Raman spectrum of the film spin-coated and then irradiated with ultraviolet rays (red line), it can be seen that new peaks indicating conjugated ene-yne appear at 1500 cm⁻¹ (C═C) and 2070 cm⁻¹ (C≡C) after irradiated with ultraviolet rays. These peaks typically appear when polydiacetylene is formed, indicating that polydiacetylene is successfully formed from HDO in the film by ultraviolet irradiation.

Referring to FIG. 7D, from the Raman spectrum of the conductive ink composition containing HDO and PEDOT: PSS (red line) and the Raman spectrum of PEDOT: PSS itself (black line), it can be seen that the peak of the symmetric Cα=Cβ stretching band of PEDOT (about 1440 cm⁻¹) has been moved by the addition of HDO. This indicates that the addition of HDO changed the structure of PEDOT from benzoid structure to quinoid structure. The benzoide structure means that the conductive PEDOT has the shape as the coil surrounded by the non-conductive PSS, while the quinoid structure, in contrast, has a linear or extended coil form in which the conductive PEDOT has a longer conjugate length. Therefore, as the form of PEDOT is linearly lengthened by the addition of HDO, conductivity may be improved.

Referring to FIG. 7E, from the X-ray diffraction (XRD) of the conductive ink composition containing HDO and PEDOT:PSS (red line) and the XRD of PEDOT:PSS itself (black line), structural changes could be observed as shown in FIG. 7D. The peak of the original PEDOT:PSS was wide, but the peak intensity of the mixture of PEDOT:PSS and HDO increased. The increase in peak intensity is due to an increase in crystallinity due to the HDO's self-assembly. In addition, the peak representing the π-π stacking distance between the PEDOT chains (about 25 degrees) was moved to larger degrees. This means that the distance between the PEDOT chains decreased from 3.5 Å to 3.44 Å when calculated using Bragg's law. This increased the π-π interchain coupling between the PEDOT chains and thus improving conductivity.

Referring to FIG. 7F, due to the structural change, the conductivity of the PEDOT:PSS film containing HDO was 3,007 S/cm, but the conductivity was reduced to 1,667 S/m after 254 nm UV irradiation, which was presumed to be due to the photo-oxidation of PEDOT. After the development process with DI water, the conductivity increased again, which was presumed to be due to the wash away of the non-conductive PSS.

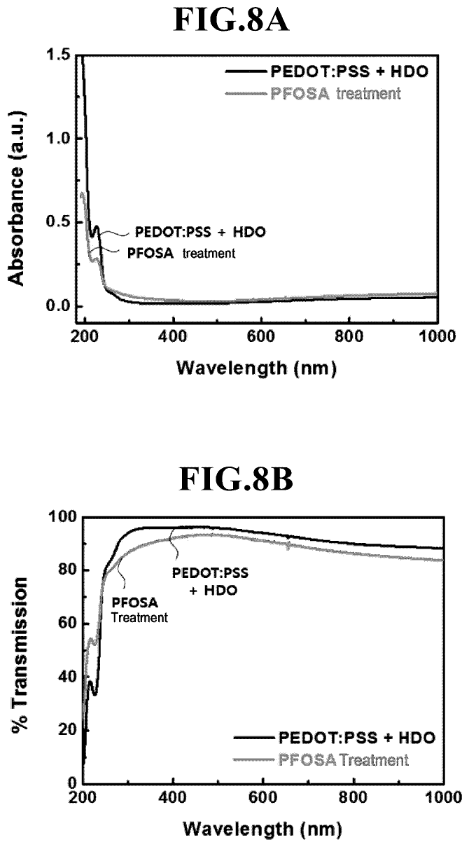

FIGS. 8A and 8B are, respectively, graphs showing UV-vis absorption spectra and transmission spectra of the conductive pattern obtained by performing Fine Pattern Preparation Example 1 using the conductive ink composition according to Conductive Ink Preparation Example 6 and the doped conductive pattern obtained by performing Fine Pattern Doping Example 1 using the conductive pattern.

Referring to FIG. 8A, the absorption band appearing in the 230 nm region of the conductive pattern (PEDOT:PSS+HDO) before being doped are due to PSS, and the intensity of this absorption band is reduced in the conductive pattern doped with PFOSA (PFOSA treatment). This means that the PSS in the PEDOT: PSS thin film is partially removed during the washing after doping with PFOSA, and further, the PSS of the PEDOT:PSS may be replaced by the perfluorinated acid by the perfluorinated acid doping.

Referring to FIG. 8B, both the conductive pattern (PEDOT:PSS+HDO) before doping and the doped conductive pattern (PFOSA treatment) are confirmed to exhibit excellent transmittance in the visible light region, and thus, it will be possible to replace transparent electrode materials such as ITO.

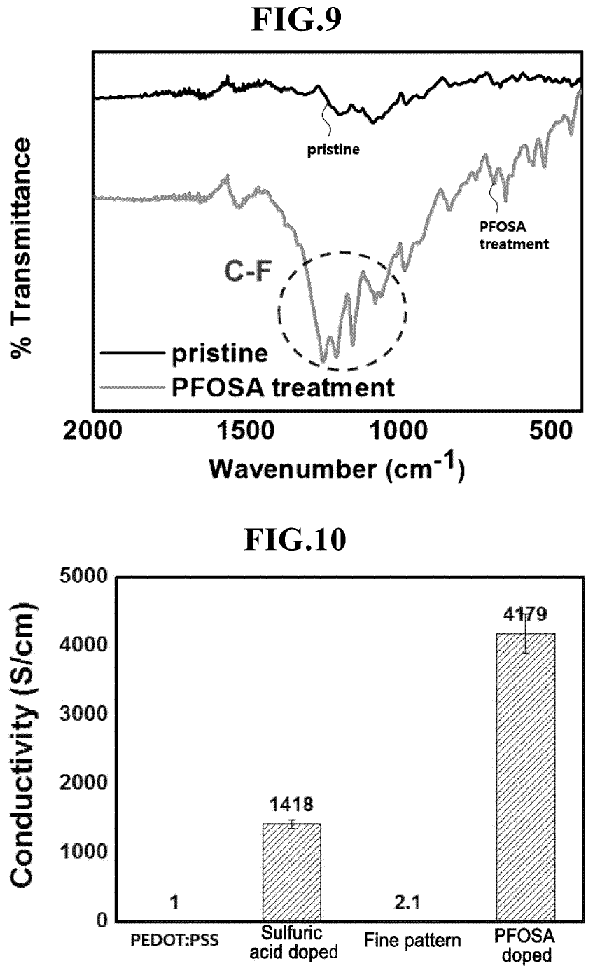

FIG. 9 shows infrared spectra of the conductive film obtained during performing Fine Pattern Preparation Example 1 using the conductive ink composition according to Conductive Ink Preparation Example 6 and the doped conductive film obtained by performing Fine Pattern Doping Example 1 on the conductive film.

Referring to FIG. 9, relative to the conductive film (pristine), the PEDOT:PSS thin film doped with perfluorosulfonic acid (PFOSA treatment) showed a typical perfluorosulfonic acid peak at 1280 cm⁻¹. This means that the perfluorinated acid is doped in the PEDOT: PSS thin film.

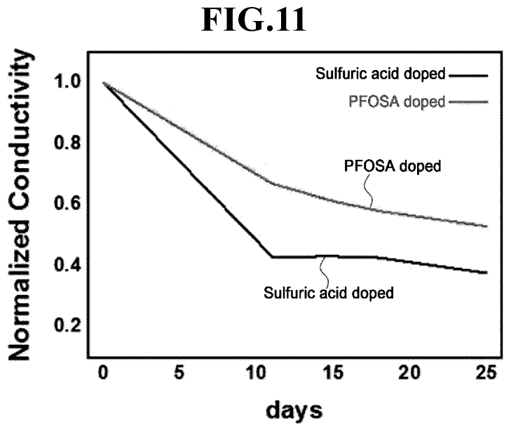

FIG. 10 is a graph showing the conductivity of PEDOT:PSS film, the fine pattern obtained according to the Fine Pattern Preparation Example 1 using the conductive ink composition of the Conductive Ink Preparation Example 1, the fine pattern doped with sulfuric acid, and the fine pattern doped with PFOSA.

Referring to FIG. 10, compared to the PEDOT:PSS film obtained by spin coating the PEDOT:PSS aqueous solution, the conductivity of the fine pattern obtained according to the Fine Pattern Preparation Example 1 using the conductive ink composition according to Conductive Ink Preparation Example 1 (containing 13 parts by weight of HDO) increased by about two times. In the case of sulfuric acid doping according to the Fine Pattern Doping Example 2, the conductivity of the doped fine pattern was greatly increased to about 1418 S/cm. However, when the fine pattern is PFOSA doped in accordance with the Fine Pattern Doping Example 1 instead of sulfuric acid, it can be seen that the conductivity of the doped fine pattern significantly increased to about 4179 S/cm. As such, when the content of the HDO in the conductive ink composition is relatively low and the conductivity after forming the fine pattern is not high, the conductivity may be greatly improved by doping PFOSA or the like.

FIG. 11 is a graph showing the relative change in conductivity over time after doping fine pattern with sulfuric acid or PFOSA.

Referring to FIG. 11, in the case of doping with sulfuric acid, the conductivity greatly decreases with time after doping, whereas in the case of doping with PFOSA, the decrease in conductivity with time after doping was not as large as in case of doping with sulfuric acid. This was presumably due to the decomposition and oxidation of polydiacetylene due to the strongly acidic sulfuric acid, thereby reducing the doping effect. In addition, the fine pattern treated with perfluorinated acid (PFOSA) shows stability against humidity and organic solvent vapor.

In the above, the present invention has been described in detail with reference to preferred embodiments, but the present invention is not limited to the above embodiments, and various modifications and changes by those skilled in the art is possible within the spirit and scope of the present invention.

1. A conductive ink comprising a conductive polymer and a diacetylene diol monomer represented by Chemical Formula 1 below:
HO—(R₁)ₙ—C≡C—C≡C—(R₂)ₘ—OH [Chemical Formula 1]
In Chemical Formula 1,
n and m are 1 to 10 irrespective of each other,
R₁ and R₂, regardless of each other, are CRₐR_{b} or (CRₐR_{b})ₓO,
Rₐ and R_{b} are each independently hydrogen or halogen, and x is an integer of 1 to 3.

2. The conductive ink according to claim 1, wherein, in Chemical Formula 1, R₁ and R₂ are both CH₂, and n and m are integers of 1 to 4 irrespective of each other.

3. The conductive ink according to claim 1, wherein the conductive polymer has a monomer represented by Chemical Formula 2 below: 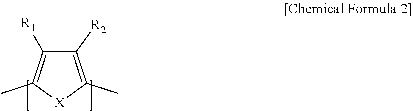
In Chemical Formula 2,
X is S or Se,
R₁ and R₂ are independently of each other hydrogen, halogen, hydroxy, alkyl of C1-C10, alkyloxy of C1-C10, or R₁ and R₂ join together to form a 3 to 5-membered alkylene, alkenylene, or alkylenedioxy group.

4. The conductive ink according to claim 3, wherein the conductive polymer is PEDOT (poly (3,4-ethylenedioxythiophene)).

5. The conductive ink according to claim 1, further comprises a polymer anion which is a polymerized carboxylic acid or polymerized sulfonic acid.

6. The conductive ink according to claim 1, further comprises water, alcohols, or mixtures thereof as a solvent.

7. The conductive ink according to claim 1, wherein the diacetylene diol monomer is contained in an amount of 1 to 600 parts by weight based on 100 parts by weight of the conductive polymer.

8. The conductive ink according to claim 7, wherein the diacetylene diol monomer is contained in an amount of 100 to 400 parts by weight.

9. The conductive ink according to claim 8, wherein the diacetylene diol monomer is contained in an amount of 100 to 250 parts by weight.

10. A preparation method for a fine pattern, comprising:
forming a conductive film by coating a conductive ink including a conductive polymer and a diacetylene diol monomer represented by the following Chemical Formula 1 on a substrate;
disposing a photomask on the conductive film and irradiating ultraviolet rays on the photomask to provide a first region having the conductive polymer and a polydiacetylene formed by crosslinking the diacetylene diol monomer and a second region in which the diacetylene diol monomer remains in the conductive film; and
selectively removing the second region to form a conductive polymer fine pattern:
HO—(R₁)ₙ—C≡C—C≡C—(R₂)ₘ—OH [Chemical Formula 1]
In Chemical Formula 1,
n and m are 1 to 10 irrespective of each other,
R₁ and R₂, regardless of each other, are CRₐR_{b} or (CRₐR_{b})ₓO,
Rₐ and R_{b} are each independently hydrogen or halogen, and x is an integer of 1 to 3.

11. The method according to claim 10, wherein the substrate is a silicon wafer, glass substrate, plastic substrate, paper or metal substrate.

12. The method according to claim 10, wherein the conductive ink contains 0.1 to 300 parts by weight of the diacetylene diol based on 100 parts by weight of the conductive polymer.

13. The method according to claim 10, wherein the selectively removing of the second region is performed using water, alcohol, or a mixture thereof.

14. The method according to claim 10, further comprising doping the conductive polymer fine pattern with one or more dopants selected from the group consisting of perfluorinated acid, sulfuric acid, sulfonic acid, formic acid, hydrochloric acid, perchloric acid, nitric acid, acetic acid, DMF (dimethylformamide), DMSO (dimethyl sulfoxide), hydroquinone, catechol, and ethylene glycol.

15. The method according to claim 14, wherein the dopant is perfluorinated acid represented by the Chemical Formula 3 below:
CF₃—(CF₂)ₙ-A [Chemical Formula 3]
In Chemical Formula 3,
n is an integer from 3 to 20, and A is SO₃H, OPO₃H or CO₂H.

16. The method according to claim 15, wherein n is an integer from 6 to 8, and A is SO₃H.

17. The method according to claim 15, wherein the conductive polymer fine pattern is an electrode of an organic electronic device.

18. Film or pattern comprising a conductive polymer and polydiacetylene represented by the following Chemical Formula 1A: 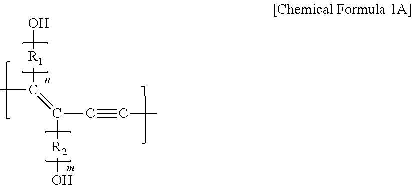
In Chemical Formula 1A,
R₁ and R₂ are CRₐR_{b} or (CRₐR_{b})ₓO irrespective of each other,
Rₐ and R_{b} are hydrogen or a halogen group regardless of each other,
x is an integer of 1 to 3, and
n and m are integers of 1 to 10 irrespective of each other

19. The film or pattern according to claim 18, further comprising perfluorinated acid represented by the Chemical Formula 3 below:
CF₃—(CF₂)ₙ-A [Chemical Formula 3]
In Chemical Formula 3,
n is an integer from 3 to 20, and A is SO₃H, OPO₃H or CO₂H.

20. The film or pattern according to claim 18, further comprising a polymer anion which is a polymerized carboxylic acid or polymerized sulfonic acid.
